(19) United States
(12) Patent Application Publication
(10) Pub. No.: US 2005/0285227 A1
(43) Pub. Date: Dec. 29, 2005

(54) Semiconductor device

(76) Inventor: Hiroaki Takasu, Chiba-shi (JP)

Correspondence Address: BRUCE L. ADAMS, ESQ., 50 BROADWAY-31ST FLOOR, NEW YORK, NY, 10004, US

(21) Appl. No.: 11/155,955

(22) Filed: Jun. 17, 2005

(30) Foreign Application Priority Data
Jun. 29, 2004 (JP) 2004-191071

(51) Int. Cl. H01L 29/00

(52) U.S. Cl. 257/537

(57) ABSTRACT

A semiconductor device is constituted by a P-type thin film resistor formed of a P-type semiconductor thin film and an N-type thin film resistor formed of an N-type semiconductor thin film, in order to avoid variation in resistance in the case of stress application. Further, a structure is adopted in which the P-type thin film resistor and the N-type thin film resistor are laminated vertically in a contact manner or arranged horizontally in a contact manner. Also, the P-type thin film resistor and the N-type thin film resistor share a contact region at the end of a resistor, which defines a unit resistance in the bleeder resistor circuit.

### BACKGROUND OF THE INVENTION

1. Field of the Invention

The present invention relates to a semiconductor device, more particularly, to a semiconductor device having a thin film resistor, a bleeder resistor circuit in which a thin film resistor is used, and a semiconductor device having such a bleeder resistor circuit.

2. Description of the Related Art

A bleeder resistor composed of plural polysilicon resistors has been generally used in an analog integrated circuit such as a voltage detector. Further, in order to manufacture an analog integrated circuit with high precision a devised example in which a potential of a conductor arranged over an upper surface or under a lower surface of a polysilicon resistor is fixed to obtain a desired resistance (divided voltage ratio) with the purpose of obtaining a resistor divided voltage ratio with higher precision can be found (for example, refer to JP 09-321229 A (FIG. 1)).

However, since a conventional thin film resistor is formed by one of a P-type or an N-type semiconductor thin film resistor, a bleeder resistor circuit composed of the thin film transistors has a problem in which, when stress is applied to the thin film resistors under packaging by resin, for example, resistance changes, which usually leads to the variation of the divided voltage ratio thereof.

### SUMMARY OF THE INVENTION

The present invention has been made to solve the above-mentioned problem, and therefore has an object to provide a bleeder resistor circuit with high precision in which: an initial resistance value is held after packaging; and an accurate divided voltage ratio can be held, and to provide a semiconductor device with high precision in which such a bleeder resistor circuit is used, for example, a semiconductor device such as a voltage detector or a voltage regulator, with its smaller occupation area.

To achieve the aforementioned object the present invention provides following means: a thin film resistor, which is mainly used in a bleeder resistor circuit, is constituted by a P-type thin film resistor formed of a P-type semiconductor thin film and an N-type thin film resistor formed of an N-type semiconductor thin film. Further, a unit resistance is defined by a resistance of a resistor formed by electrically contacting a P-type thin film resistor with an N-type thin film resistor in a vertical direction or horizontal direction in the bleeder resistor circuit in order to cancel variations, which are caused by a piezoelectric effect, as described later, in each resistance of the P-type thin film resistor and the N-type thin film resistor.

Further, a contact region in each end of the resistor, which defines a unit resistance in a bleeder resistor circuit, is provided so as to penetrate an upper layer of the resistor laminating the P-type thin film resistor and the N-type thin film resistor to have contact in a vertical direction; thus a single contact region can establish electrical connection both to the P-type thin film resistor and the N-type thin film resistor. Moreover, a contact region in each end of the resistor, which defines a unit resistance in a bleeder resistor circuit, is provided so as to overlap both the P-type thin film resistor and the N-type thin film resistor arranged to have contact in a horizontal direction; and a single contact region can establish electrical connection both to the P-type thin film resistor and the N-type thin film resistor.

Hereinafter, description will be made to the variation in resistance caused by the piezoelectric effect and its influence on the bleeder resistor circuit.

When stress is applied to a film resistor, the resistance of the thin film resistor varies due to the piezoelectric effect. Direction of the variation in resistance of the P-type thin film resistor and of the N-type thin film resistor is inverse such that, for example, the resistance of the P-type thin film resistor decreases while the resistance of the N-type thin film resistor increases due to the direction of the stress applied to the resistor.

Since packaging of an integrated circuit by resin generates stress, resistance of the thin film resistor is varied due to the piezoelectric effect as described above. The bleeder resistor circuit is designed to give an accurate divided voltage ratio; however, resistance of the individual resistors in the circuit varies, the divided voltage ratio varies accordingly.

The thin film resistor according to the present invention is constituted by a P-type thin film resistor formed of a P-type semiconductor thin film and an N-type thin film resistor formed of an N-type semiconductor thin film. When a stress is applied, variations in the respective resistance cancel, net variation in the resistance of the entire thin film resistor can be avoided. Further, in a bleeder resistor circuit, a unit resistance is defined by resistance of a resistor formed by electrically contacting a P-type thin film resistor with an N-type thin film resistor. Thus, even if a stress is applied, an accurate divided voltage ratio can be maintained since variations in the resistance of the individual resistor cancel each other. Moreover, reduction of the occupation area can be attained since electrical connection among the P-type thin film resistor, the N-type thin film resistor, and wiring is established collectively by a common contact hole.

### BRIEF DESCRIPTION OF THE DRAWINGS

In the accompanying drawings:

FIG. 1 is a schematic sectional view showing Embodiment 1 of the present invention;

FIG. 2 is a schematic plan view showing Embodiment 2 of the present invention;

FIG. 3 shows an example of a block diagram of a voltage detector in which a bleeder resistor circuit of the present invention can be used; and

FIG. 4 shows an example of a block diagram of a voltage regulator in which a bleeder resistor circuit of the present invention can be used.

### DETAILED DESCRIPTION OF THE PREFERRED EMBODIMENTS

Hereinafter, description will be made of preferred embodiments of the present invention with reference to the drawings.

### EMBODIMENT 1

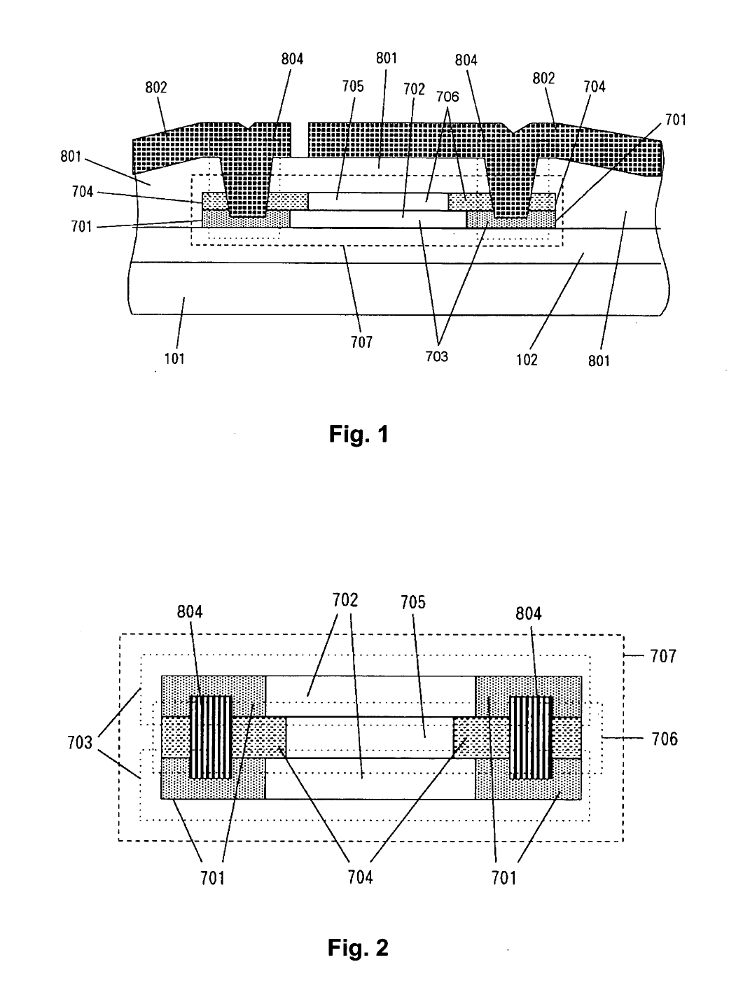

FIG. 1 is a schematic sectional view showing a semiconductor thin film resistor in a semiconductor device according to Embodiment 1 of the present invention.

A first insulating film 102 is formed on a semiconductor substrate 101. A P-type polysilicon resistor 703 having a P-type high resistance region 702 sandwiched by P-type low resistance regions 701, to which electrical contact with a wiring 802 formed of aluminum or other conductive metal is made, containing dense P-type impurities and an N-type polysilicon resistor 706 having an N-type high resistance region 705 sandwiched by N-type low resistance regions 704 for an electrical contact with the wiring 802 containing dense N-type impurities are formed on the first insulating film 102. The N-type polysilicon resistor 706 is formed so as to contact with an upper surface of the P-type polysilicon resistor 703. A contact hole 804 is formed in each of the P-type low resistance region 701 and in each of the N-type low resistance region 704 to have an electrical contact with the wiring 802 formed of aluminum or other conductive metal.

Here, the contact hole 804 is formed to penetrate the low resistance region 704 of the N-type polysilicon resistor 706, which is formed to contact with the upper surface of the P-type polysilicon resistor 703, to reach the low resistance region 701 of the P-type polysilicon resistor 703. In this structure a common contact hole gives connection among the N-type polysilicon resistor 706, the P-type polysilicon resistor 703, and the wiring 802 formed of aluminum or other conductive metal.

Further, as regards a resistance of a resistor 707 obtained by a structure in which a P-type polysilicon resistor 703 and an N-type polysilicon resistor 706 are arranged vertically in a contact manner, variation in the resistance of the P-type polysilicon resistor 703 and variation in the resistance of the N-type polysilicon resistor 706 cancel even if a stress is applied by resin packaging or the like, and therefore, an initial resistance can be held.

Shown in FIG. 1 is an example of a structure of the resistor 707 in which a P-type polysilicon resistor 703 is arranged as a lower layer while an N-type polysilicon resistor 706 is arranged as an upper layer contacting with the P-type polysilicon resistor 703. However, the N-type polysilicon resistor 706 can be arranged as a lower layer. Also, the resistor 707 may be formed by combining P-type polysilicon resistors 703 with N-type polysilicon resistors 706 for plural layers instead of one P-type polysilicon resistor 703 and one N-type polysilicon resistor 706.

Moreover, the embodiment of FIG. 1 shows an example in which the polysilicon thin film resistor is used as the semiconductor thin film resistor; however, the semiconductor thin film resistor of the present invention is not limited to the polysilicon thin film resistor. The same effect is obtained also with a composite film formed of another material and a polysilicon thin film such as a composite film formed of a high-melting point metal and a polysilicon thin film. Furthermore, the wiring 802 connected at an end of the resistor 707 is formed so as to sufficiently cover the P-type high resistance region 702, which is sandwiched by the P-type low resistance regions 701 containing dense P-type impurities, and the N-type high resistance region 705, which is sandwiched by the N-type low resistance regions 704 containing dense N-type impurities, in the resistor 707 to avoid the influence of hydrogen introduced into the resistor 707 in a manufacturing step, for example, of forming a protective film such as a plasma nitride film on a semiconductor device although this is not shown in the figure.

### EMBODIMENT 2

FIG. 2 is a schematic plan view showing a semiconductor thin film resistor in a semiconductor device according to Embodiment 2 of the present invention.

Different from Embodiment 1 shown in FIG. 1, Embodiment 2 provides a structure in which the P-type polysilicon resistor 703 and the N-type polysilicon resistor 706 are arranged to be adjacent to each other to have a direct contact in a horizontal direction.

Two P-type polysilicon resistors 703 each including the P-type high resistance region 702 sandwiched by the P-type low resistance regions 701 containing dense P-type impurities are disposed at the both side of an N-type polysilicon resistor 706 including the N-type high resistance region 705 sandwiched by the N-type low resistance regions 704 containing dense N-type.

Here, a contact hole 804 is formed so as to overlap the low resistance region 701 in the P-type polysilicon resistor 703 and the low resistance region 704 in the N-type polysilicon resistor 706 in each end of the resistor 707. In this structure a common contact hole can give connection among the N-type polysilicon resistor 706, the P-type polysilicon resistor 703, and the wiring, which is not shown in FIG. 2, formed of aluminum or other conductive metal.

Embodiment of FIG. 2 shows the structure in which one N-type polysilicon resistor 706 is sandwiched by two P-type polysilicon resistors 703 at both sides. However, on the contrary, two N-type polysilicon resistors 706 may be arranged so as to sandwich one P-type polysilicon resistor 703 at both sides, or one N-type polysilicon resistor 706 maybe combined with one P-type polysilicon resistor 703 so as to be adjacent to each other in contact. Alternatively, plural N-type polysilicon resistors 706 and plural P-type polysilicon resistors 703 may be arranged in a contact manner.

### EMBODIMENT 3

When a resistor 707, which is obtained by combining the P-type polysilicon resistor 703 with the N-type polysilicon resistor 706 shown in FIGS. 1 and 2, is defined as a unit of a bleeder circuit, and plural resistors 707 are formed to construct an entire bleeder circuit, an accurate divided voltage ratio can be held even if a stress is applied by resin packaging or the like. Such a bleeder resistor circuit can give high precision to a semiconductor device such as a voltage detector or a voltage regulator.

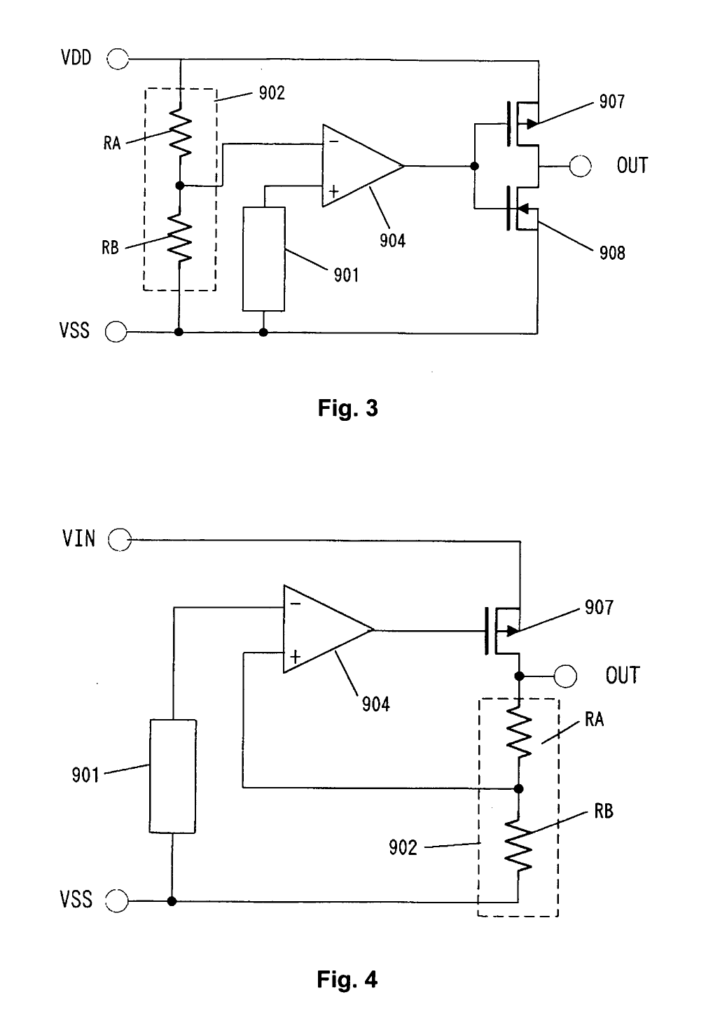

FIG. 3 shows an example of a block diagram of a voltage regulator in which a bleeder resistor circuit according to the present invention can be used. A simple circuit is shown for simplicity. Functions may, of course, be added in an actual product when necessary.

Basic circuit building elements for a voltage detector are a reference voltage circuit 901, a bleeder resistor circuit 902, and an error amplifier 904. Further an N-type transistor 908, a P-type transistor 907 and etc. are added. Hereinafter a part of operation of the voltage detector is explained briefly.

An inverting input to the error amplifier 904 is a divided voltage Vr divided in the bleeder resistor circuit 902, that is, RB/(RA+RB)*VDD. A reference voltage. Vref of the reference voltage circuit 901 is set to be equal to the divided voltage Vr at which a power source voltage VDD is equal to a predetermined detection voltage Vdet. That is, an equation Vref=RB/(RA+RB)*Vdet holds. When the power source voltage VDD is larger than the predetermined voltage Vdet, it is designed such that an output of the error amplifier 904 is LOW. Thus, the P-type transistor 907 is turned ON while the N-type transistor 908 is turned OFF, and the power source voltage VDD appears at an output terminal OUT.

When the power source voltage VDD lowers and reaches a voltage equal to or less than the detection voltage Vdet, the ground level VSS appears at the output terminal OUT.

As described above, the basic operation is performed by comparing the reference voltage Vref generated in the reference voltage circuit 901 with the divided voltage Vr divided in the bleeder resistor circuit 902 in the error amplifier 904. Precision of the divided voltage Vr divided in the bleeder resistor circuit 902 is, therefore, extremely important. When the precision of the divided voltage in the bleeder resistor circuit 902 is low, an input voltage to the error amplifier 904 varies, a constant predetermined detection voltage or a release voltage, at which the detector starts to output the power source voltage VDD and whose voltage precision is similar to that required for the detection voltage, cannot be obtained as a result. The use of the bleeder resistor circuit according to the present invention can provide a high precision divided voltage since variation in the resistance is small even after resin packaging of an integrated circuit. Product yield of the integrated circuit is therefore improved, and a more precise voltage detector can be manufactured.

### EMBODIMENT 4

FIG. 4 shows an example of a block diagram of a voltage regulator in which a bleeder resistor circuit according to the present invention can be used. A simple circuit is shown for simplicity. Functions can be added in an actual product when necessary.

Basic circuit building elements for a voltage regulator are a reference voltage circuit 901, a bleeder resistor circuit 902, an error amplifier 904, a P-type transistor 907 that works as a current control transistor. Hereinafter a part of operation of the voltage regulator will be simply explained.

The error amplifier 904 supplies gate voltage necessary for obtaining a predetermined constant output voltage VOUT, which is independent of variation in input voltage VIN, to the P-type transistor 907 after comparing the divided voltage Vr divided in the bleeder resistor circuit 902 with the reference voltage Vref generated in the reference voltage circuit 901. As in the voltage detector described with FIG. 3, the basic operation of the voltage regulator is performed by comparing the reference voltage Vref generated in the reference voltage circuit 901 with the divided voltage Vr divided in the bleeder resistor circuit 902 in the error amplifier 904. The precision of the divided voltage Vr divided in the bleeder resistor circuit 902 is, therefore, extremely important. When the precision of the divided voltage in the bleeder resistor circuit 902 is low, the predetermined constant output voltage VOUT cannot be obtained since the input voltage to the error amplifier 904 varies. The use of the bleeder resistor circuit according to the present invention can provide a high precision divided voltage since variation in the resistance is small even after resin packaging of an integrated circuit. Product yield of the integrated circuit is therefore improved, and a more precise voltage detector can be manufactured.

Hereinabove, the embodiments of the present invention have been described in which the polysilicon thin film resistor is used as the semiconductor thin film resistor. However, the semiconductor thin film resistor of the present invention is not limited to the polysilicon thin film resistor. A composite film which includes plural materials containing a high-melting point metal and the like and which cancels the variation amounts in the resistance due to the piezoelectric effect shows the same effect.

According to the present invention, a semiconductor device such as a semiconductor device including a thin film resistor, a bleeder resistor circuit in which a thin film resistor is used, or a semiconductor device including a bleeder resistor circuit can be realized. In particular, a high precision semiconductor device such as a voltage detector or a voltage regulator can be realized.

1. A semiconductor device comprising: a thin film resistor constituted by plural composite films, each of which is formed of plural materials, and which are arranged to contact directly to mutually cancel variation in resistance thereof due to a piezoelectric effect.

2. A semiconductor device according to claim 1, wherein the thin film resistor comprises a P-type thin film resistor formed of a P-type semiconductor thin film and an N-type thin film resistor formed of an N-type semiconductor thin film contacting each other.

3. A semiconductor device according to claim 2, further comprising a bleeder resistor circuit having a plurality of the thin film resistors, wherein a unit resistance in the bleeder resistor circuit is defined by a resistance of the thin film resistor constituted by the P-type thin film resistor and the N-type thin film resistor contacting each other.

4. A semiconductor device according to claim 3, wherein the thin film resistor which defines the unit resistance in the bleeder resistor circuit is formed by the P-type thin film resistor and the N-type thin film resistor piled in a vertical direction contacting each other.

5. A semiconductor device according to claim 3, wherein the thin film resistor which defines the unit resistance in the bleeder resistor circuit is formed by the P-type thin film resistor and the N-type thin film resistor disposed in a horizontal direction contacting each other.

6. A semiconductor device according to claim 4, wherein a contact hole at an end of the thin film resistor which defines the unit resistance in the bleeder resistor circuit is arranged to penetrate an upper on of the P-type thin film resistor and the N-type thin film resistor piling in the vertical direction contacting each other; and an electrical connection to the P-type thin film resistor and to the N-type thin film resistor is made by the contact hole.

7. A semiconductor device according to claim 5, wherein a contact hole at an end of the thin film resistor which defines the unit resistance in the bleeder resistor circuit is arranged to overlap both the P-type thin film resistor and the N-type thin film resistor disposed in the horizontal direction connecting each other; and electrical connection between the P-type thin film resistor and the N-type thin film resistor is made by the contact hole.

8. A semiconductor device according to claim 1, wherein the composite film formed of the plural materials is comprises of a composite film containing a high-melting point metal.
